(19) United States
(12) Patent Application Publication
(10) Pub. No.: US 2024/0203690 A1
(43) Pub. Date: Jun. 20, 2024

(54) SUBSTRATE TREATMENT APPARATUS AND PLASMA DENSITY CONTROL METHOD

(71) Applicant: SEMES CO., LTD., Cheonan-si (KR)

(72) Inventors: Hyoung Kyu SON, Seoul (KR); Sang Hyun PARK, Yongin-si (KR); Yun Sang KIM, Seongnam-si (KR); Yoon Seok CHOI, Suwon-si (KR); Ju Yong JANG, Seongnam-si (KR)

(73) Assignee: SEMES CO., LTD., Cheonan-si (KR)

(21) Appl. No.: 18/540,731

(22) Filed: Dec. 14, 2023

(30) Foreign Application Priority Data
Dec. 15, 2022 (KR) 10-2022-0175717

(51) Int. Cl. H01J 37/32

(52) U.S. Cl. CPC H01J 37/32155; H01J 37/3211; H01J 2237/002; H01J 2237/327

(57) ABSTRACT

Proposed is a substrate treatment apparatus and a plasma density control method, and relates to a technology of controlling non-uniformity of plasma density in a substrate treatment process using plasma so that a plasma sheath is adjusted, thereby precisely controlling the substrate treatment process.

### CROSS REFERENCE TO RELATED APPLICATION

The present application claims priority to Korean Patent Application No. 10-2022-0175717, filed on Dec. 15, 2022, the entire contents of which are herein incorporated by reference.

### BACKGROUND OF THE INVENTION

### Field of the Invention

The present disclosure is a substrate treatment apparatus and a plasma density control method. More specifically, the present disclosure relates to a technology in which non-uniformity of plasma density in a substrate treatment process using plasma is controlled so that a plasma sheath is adjusted, thereby precisely controlling the substrate treatment process.

### Description of the Related Art

Various technologies for forming a plasma environment and performing a semiconductor process have been proposed.

As an example, an Inductively Coupled Plasma (ICP) substrate treatment apparatus may excite a process gas supplied into a process chamber into a plasma state through inductive coils disposed outside the process chamber.

In a treatment space of such a chamber, a plasma density distribution for each region and plasma sheath are significantly important factors when a substrate treatment using plasma is performed.

A coil antenna is applied so as to create a plasma environment in the treatment space inside the chamber.

As an example, since a plasma generation unit may include an inner coil and an outer coil, there is a problem that a process parameter cannot be accurately and precisely adjusted due to increased control factors when power is individually applied to the inner coil and the outer coil and a direction and intensity of the power are individually adjusted.

### DOCUMENT OF RELATED ART

(Patent Document 1) Korean Patent No. 10-1558295

### SUMMARY OF THE INVENTION

Accordingly, the present disclosure has been made keeping in mind the above problems occurring in the related art, and an objective of the present disclosure is to provide a method capable of controlling plasma sheath by controlling non-uniformity of plasma density.

Particularly, since a plasma generation unit may include an inner coil and an outer coil, there is a problem that a process parameter cannot be accurately and precisely adjusted due to increased control factors when power is individually applied to the inner coil and the outer coil and a direction and intensity of the power are individually adjusted. An objective of the present disclosure is to solve this problem.

The objectives of the present disclosure are not limited thereto, and other objectives and other advantages of the present disclosure will be understood from the following description.

In order to achieve the objectives as described above, according to an embodiment of the present disclosure, there is provided a substrate treatment apparatus including: a chamber provided with a treatment space in which a plasma substrate treatment process is performed; a substrate supporting unit which is disposed in the treatment space and on which a substrate to be treated is seated; an inner coil wound in a first direction; an outer coil disposed relatively outside the inner coil and wound in a second direction opposite to the first direction; a current regulator connecting the inner coil and the outer coil in series between the inner coil and the outer coil, the current regulator being configured to convert a current; and an RF power supply part configured to selectively supply power to the inner coil or the outer coil so as to form plasma in the treatment space.

Preferably, a first side distal end of the inner coil and a first side distal end of the outer coil may be connected to the RF power supply part, and a second side distal end of the inner coil and a second side distal end of the outer coil may be connected to the current regulator, so that the inner coil and the outer coil may be connected with each other in series via the current regulator.

Furthermore, the substrate treatment apparatus may further include a controller configured to control the RF power supply part so that power intensity is adjusted and RF power is selectively supplied to the inner coil and the outer coil, the controller being configured to control the current regulator so that current intensity between the inner coil and the outer coil is changed.

Here, the controller may be configured to adjust plasma density by controlling the power of the RF power supply part and by controlling the current of the current regulator such that a plasma density value of a center region of the substrate which is to be treated and which is seated on the substrate supporting unit and a plasma density value of an outer region of the substrate are different from each other.

As an example, the RF power supply part may be configured to apply the power to the inner coil, and the current regulator may be configured to increase or decrease intensity of current output from the inner coil and to apply the current to the outer coil.

As an example, the RF power supply part may be configured to apply the power to the outer coil, and the current regulator may be configured to decrease or increase intensity of current output from the outer coil and to apply the current to the inner coil.

Preferably, the RF power supply part may include: an RF power generator configured to generate RF power; a power regulator configured to adjust a supply direction and intensity of the power; and an RF filter configured to adjust a frequency band of the RF power and to output the RF power.

Furthermore, the inner coil may include a plurality of inner coils disposed in a multi-layer structure and electrically separated from each other, the outer coil may include a plurality of outer coils disposed in a multi-layer structure and electrically separated from each other corresponding to the plurality of inner coils, and the current regulator may include a plurality of current regulators which is respectively connected between the plurality of inner coils and the plurality of outer coils corresponding to the plurality of inner coils and which is configured to convert the current.

As an example, the RF power supply part may be configured to selectively apply the power to the plurality of inner coils and the plurality of outer coils, and the current regulator may be configured to individually decrease or increase intensity of the current between the plurality of inner coils and the plurality of outer coils.

As an example, the RF power supply part may include: an RF power generator configured to generate RF power; a plurality of power regulators configured to individually adjust a supply direction and intensity of the power by corresponding to the plurality of inner coils and the plurality of outer coils; and a plurality of RF filters configured to adjust a frequency band of each RF power by corresponding to the plurality of inner coils and the plurality of outer coils and to output the RF power.

Furthermore, the substrate treatment apparatus may further include: an inner body on which the inner coil is wound and in which a refrigerant flow path is formed therein; an outer body on which the outer coil is wound and in which a refrigerant flow path is formed therein; and a refrigerant supply part configured to supply a refrigerant to the refrigerant flow path of the inner body and the refrigerant flow path of the outer body.

In addition, according to an embodiment of the present disclosure, there is provided a plasma density control method including: a power applying process in which RF power is applied through an RF power supply part to a selected coil among an inner coil and an outer coil that correspond to each other; a current conversion process in which intensity of a current output from the selected coil is increased or decreased and the current is applied to a coil corresponding to the selected coil through a current regulator; and a plasma forming process in which plasma density is formed such that a plasma density value of a center region of a substrate to be treated and a plasma density value of an outer region of the substrate to be treated are different from each other.

As an example, the power applying process may be performed such that the RF power is applied to the inner coil through the RF power supply part, the current conversion process may be performed such that intensity of a current output from the inner coil is decreased and applied to the outer coil through the current regulator, and the plasma forming process may be performed to form the plasma density such that the plasma density value of the center region of the substrate to be treated is relatively higher than the plasma density value of the outer region of the substrate to be treated.

As an example, the power applying process may be performed such that the RF power is applied to the outer coil through the RF power supply part, the current conversion process may be performed such that intensity of a current output from the outer coil is decreased and applied to the inner coil through the current regulator, and the plasma forming process may be performed to form the plasma density such that the plasma density value of the outer region of the substrate to be treated is relatively higher than the plasma density value of the center region of the substrate to be treated.

As an example, the power applying process may be performed such that the RF power is applied to the inner coil through the RF power supply part, the current conversion process may be performed such that intensity of a current output from the inner coil is increased and applied to the outer coil through the current regulator, and the plasma forming process may be performed to form the plasma density such that the plasma density value of the center region of the substrate to be treated is relatively higher than the plasma density value of the outer region of the substrate to be treated.

As an example, the power applying process may be performed such that the RF power is applied to the outer coil through the RF power supply part, the current conversion process may be performed such that intensity of a current output from the outer coil is increased and applied to the inner coil through the current regulator, and the plasma forming process may be performed to form the plasma density such that the plasma density value of the outer region of the substrate to be treated is relatively higher than the plasma density value of the center region of the substrate to be treated.

As an example, the power applying process may be performed such that the RF power is applied through the RF power supply part to each inner coil including a plurality of inner coils, the current conversion process may be performed such that intensity of a current output from each of the inner coils is decreased and applied through the current regulator to each outer coil including a plurality of outer coils, and the plasma forming process may be performed to form the plasma density such that the plasma density value of the center region of the substrate to be treated is relatively higher than the plasma density value of the outer region of the substrate to be treated.

As an example, the power applying process may be performed such that the RF power is applied through the RF power supply part to each outer coil including a plurality of outer coils, the current conversion process may be performed such that intensity of a current output from each of the outer coils is decreased and applied through the current regulator to each inner coil including a plurality of inner coils, and the plasma forming process may be performed to form the plasma density such that the plasma density value of the outer region of the substrate to be treated is relatively higher than the plasma density value of the center region of the substrate to be treated.

As an example, the power applying process may be performed such that the RF power is applied through the RF power supply part to each of at least one inner coil selected among the inner coil including a plurality of inner coils and at least one outer coil corresponding to the inner coil that is not selected, the current conversion process may be performed such that intensity of a current output from each of at least one outer coil to which the RF power is applied and at least one inner coil to which the RF power is applied is increased or decreased and then is applied through the current regulator to each of at least one outer coil to which the RF power is not applied and at least one inner coil to which the RF power is not applied, and the plasma forming process may be performed to form the plasma density such that the plasma density value of the outer region of the substrate to be treated and the plasma density value of the center region of the substrate to be treated are different from each other.

Preferably, according to an embodiment of the present disclosure, there is provided a substrate treatment apparatus including: a chamber provided with a treatment space in which a plasma substrate treatment process is performed; a substrate supporting unit which is disposed in the treatment space and on which a substrate to be treated is seated; an inner coil wound in a first direction; an inner body on which the inner coil is wound and in which a refrigerant flow path is formed therein; an outer coil disposed relatively outside the inner coil and wound in a second direction opposite to the first direction; an outer body on which the outer coil is wound and in which a refrigerant flow path is formed therein; a current regulator connecting the inner coil and the outer coil in series between the inner coil and the outer coil, the current regulator being configured to convert a current; an RF power supply part configured to selectively supply power to the inner coil or the outer coil so as to form plasma in the treatment space; a refrigerant supply part configured to supply a refrigerant to the refrigerant flow path of the inner body and the refrigerant flow path of the outer body; and a controller configured to control the RF power supply part so that power intensity is adjusted and RF power is selectively supplied to the inner coil and the outer coil, the controller being configured to control the current regulator so that current intensity between the inner coil and the outer coil is changed, thereby adjusting plasma density such that a plasma density value of a center region of the substrate to be treated and a plasma density value of an outer region of the substrate to be treated are different from each other.

According to the present disclosure, plasma sheath may be controlled by controlling non-uniformity of plasma density.

Particularly, in the present disclosure, since the inner coil and the outer coil are connected in series via the current regulator and the start points and the end points of the inner coil and the outer coil are connected to the RF power supply part, the power applied to the inner coil and the power applied to the outer coil are capable of being adjusted at the same time by using this structure, thereby being capable of more accurately and precisely controlling the plasma density.

That is, when the power is individually applied to the inner coil and the outer coil and the direction and the intensity of the power are individually adjusted, there is a problem that a process parameter cannot be accurately and precisely adjusted due to increased control factors. However, in the present disclosure, since the direction and the intensity of the power applied to the inner coil and the outer coil are adjusted by corresponding with the inner coil and the outer coil, factors to be controlled are reduced, so that the process parameter is capable of being more accurately and precisely adjusted.

Furthermore, when the coils are operated, an increase in temperature due to heat is caused, but the increase in temperature due to the operation of the coils is capable of being resolved by applying the cooling means.

Furthermore, since the RF power supply part is configured as a multi-power supply so that the direction and the intensity of the power is capable of being individually adjusted to the inner coil and the outer coil, the power supply may be more precisely controlled.

In addition, since the RF filter is provided in the RF power supply part, RF radiation noise may be blocked from being introduced.

The effects of the present disclosure are not limited to those mentioned above, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is an exemplary view illustrating a substrate treatment apparatus according to an embodiment of the present disclosure;

FIG. 2 is a view illustrating an embodiment of a plasma generation unit of the substrate treatment apparatus according to the present disclosure;

FIG. 3 is a view illustrating a configuration of an embodiment of the plasma generation unit of the substrate treatment apparatus according to the present disclosure when viewed from above;

FIG. 4 is a view illustrating the configuration of an embodiment of the plasma generation unit of the substrate treatment apparatus according to the present disclosure taken along a side surface of the plasma generation unit;

FIG. 5 is a view illustrating a configuration of an embodiment of an RF power supply part in the plasma generation unit of the substrate treatment apparatus according to the present disclosure;

FIG. 6 is a view illustrating a configuration of an embodiment of a controller in the plasma generation unit of the substrate treatment apparatus according to the present disclosure;

FIGS. 7A and 7B are views illustrating an embodiment of a cooling means of the plasma generation unit of the substrate treatment apparatus according to the present disclosure;

FIG. 8 is a flowchart illustrating an embodiment of a plasma density control method according to the present disclosure;

FIG. 9 is a flowchart illustrating an example of a process of controlling plasma density through the present disclosure;

FIG. 10 is a view illustrating an example of an operation process of the substrate treatment apparatus according to an example of the present disclosure;

FIG. 11 is a view illustrating an example in which the plasma density is controlled through the present disclosure;

FIG. 12 is a flowchart illustrating another example of the process of controlling plasma density through the present disclosure;

FIG. 13 is a view illustrating an example of the operation process of the substrate treatment apparatus according to another example of the present disclosure;

FIG. 14 is a view illustrating another example in which the plasma density is controlled through the present disclosure;

FIG. 15 is a view illustrating another embodiment of the plasma generation unit of the substrate treatment apparatus according to the present disclosure;

FIGS. 16A and 16B are views illustrating another embodiment of the cooling means of the plasma generation unit of the substrate treatment apparatus according to the present disclosure;

FIG. 17 is a flowchart illustrating another embodiment of the plasma density control method according to the present disclosure; and

FIG. 18 and FIG. 19 are views illustrating an example of the operation process of the substrate treatment apparatus according to still another example of the present disclosure.

### DETAILED DESCRIPTION OF THE INVENTION

Hereinafter, exemplary embodiments of the present disclosure will be described in detail with reference to the accompanying drawings, but the present disclosure is not limited or restricted to the embodiments.

In order to explain the present disclosure, the operational advantages of the present disclosure, and the objectives achieved by the practice of the present disclosure, the embodiments of the present disclosure are exemplified below and will be described with reference thereto.

First, the terms used in this application are only used to describe specific embodiments, and are not intended to limit the present disclosure, and a singular expression may include a plural expression unless the context clearly indicates otherwise. In addition, it should be understood that in the present disclosure, terms such as “comprise” or “have” are intended to designate that a feature, number, step, operation, component, part, or combination thereof described in the specification exists, and do not preclude the possibility of addition or existence of one or more other features or numbers, steps, operations, components, parts, or combinations thereof.

In describing the present disclosure, when it is determined that a detailed description of a related known configuration or function may obscure the gist of the present disclosure, the detailed description thereof will be omitted.

The present disclosure relates to a technology of controlling non-uniformity in plasma density in a substrate treatment process using plasma, thereby controlling plasma sheath and thereby precisely controlling the substrate treatment process.

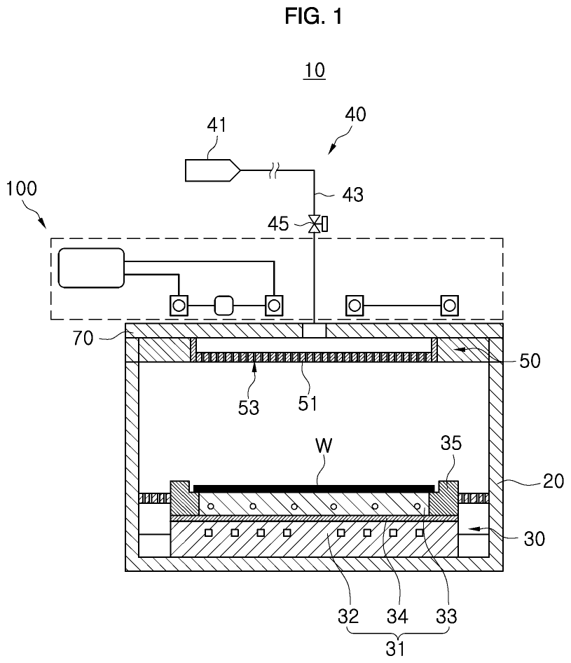

FIG. 1 is an exemplary view illustrating a substrate treatment apparatus according to an embodiment of the present disclosure.

A substrate treatment apparatus 10 may treat a substrate W by using plasma. The substrate treatment apparatus 10 may include a chamber 20, a substrate supporting unit 30, a shower head 50, a gas supply unit 40, a plasma generation unit 100, and so on.

The chamber 20 may have an inner portion provided with a treatment space in which a substrate treatment process is performed. A shape and a size of the chamber 20 may vary according to a required process and a substrate to be treated.

The substrate supporting unit 30 may be positioned in the treatment space of the chamber 20. The substrate supporting unit 30 may support the substrate W. As an example, the substrate supporting unit 30 may include an electrostatic chuck 31 and so on, the electrostatic chuck 31 being configured to suction the substrate W by using an electrostatic force. In contrast, the substrate supporting unit 30 may support the substrate W in various methods such as a mechanical clamping method, a vacuum method, and so on.

The electrostatic chuck 31 may include a base member 32, a chucking member 33, an insulating layer 34, and so on. The base member 32 may support the chucking member 33.

The chucking member 33 may support the substrate W by using the electrostatic force, the substrate W being seated on an upper portion of the chucking member 33. The chucking member 33 may be coupled to the base member 32 so that the chucking member 33 is fixed to the base member 32.

The insulating layer 34 formed of an insulator may be formed between the base member 32 and the chucking member 33 that is formed above the base member 32.

In addition, a heating member, a cooling member, and so on may be provided inside the electrostatic chuck 31 so that a process temperature of a substrate can be adjusted.

a focus ring 35 may be disposed on a peripheral region of the electrostatic chuck 31. An outer portion of the focus ring 35 may be provided such that the focus ring 35 surrounds a peripheral region of the substrate W. The focus ring 35 may control an electromagnetic field such that densities of plasma are uniformly distributed in the entire region of the substrate W. A structure and a shape of the focus ring 35 may be changed variously.

The shower head 50 may be positioned above the substrate supporting unit 30 from inside of the chamber 20. The shower head 50 may be disposed such that the shower head 50 faces the substrate supporting unit 30. The shower head 50 may include a gas injection plate 51 in order to disperse gas to the treatment space of the chamber 20. A gas injection hole 53 is formed in the gas injection plate 51, and the gas may be dispersed to the treatment space of the chamber 20 through the gas injection hole 53.

The gas supply unit 40 may supply the gas required for the substrate treatment process to the treatment space of the chamber 20. The gas supply unit 40 may include a gas supply source 41, a gas supply line 43, a gas injection nozzle (not illustrated), and so on. The gas supply line 43 may connect the gas supply source 41 and the gas injection nozzle (not illustrated) to each other. A gas valve 45 configured to open or close a passage of the gas supply line 43 or configured to adjust a flow rate of a fluid flowing along the passage may be mounted in the gas supply line 43.

In the present embodiment, the gas supply source 41, the gas supply line 43, the gas valve 45, and so on are illustrated as one for convenience of explanation. However, the configuration of the gas supply unit 40 may be varied so that various plurality of gases may be mixed or selectively supplied to the treatment space of the chamber 20 according to the substrate treatment process.

A window member 70 capable of opening or sealing the chamber 20 may be disposed on an upper portion of the shower head 50.

In order to seal an inner space of the chamber 20, the window member 70 may be formed so as to correspond to an upper shape of the chamber 20. The window member 70 may be formed of an insulating material, and may include a dielectric window. A through-hole for injecting the gas supplied from the gas supply unit 40 to the shower head 50 may be formed in the window member 70.

The plasma generation unit 100 may be disposed on an upper portion of the window member 70.

The plasma generation unit 100 may excite a process gas introduced into the treatment space of the chamber 20 into a plasma state.

In the present disclosure, the plasma generation unit 100 is proposed, in which the plasma generation unit 100 is capable of controlling plasma density of each region of the treatment space in the substrate treatment process using plasma, thereby being capable of adjusting plasma sheath and thereby being capable of precisely controlling the substrate treatment process.

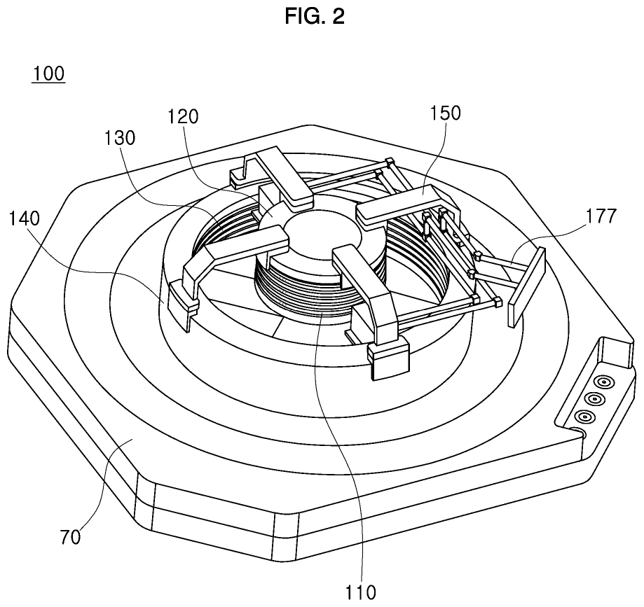

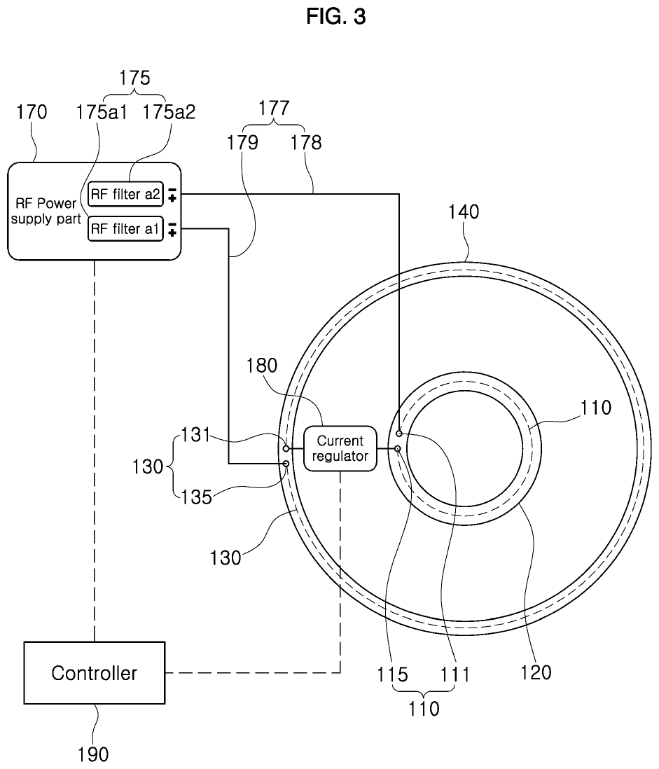

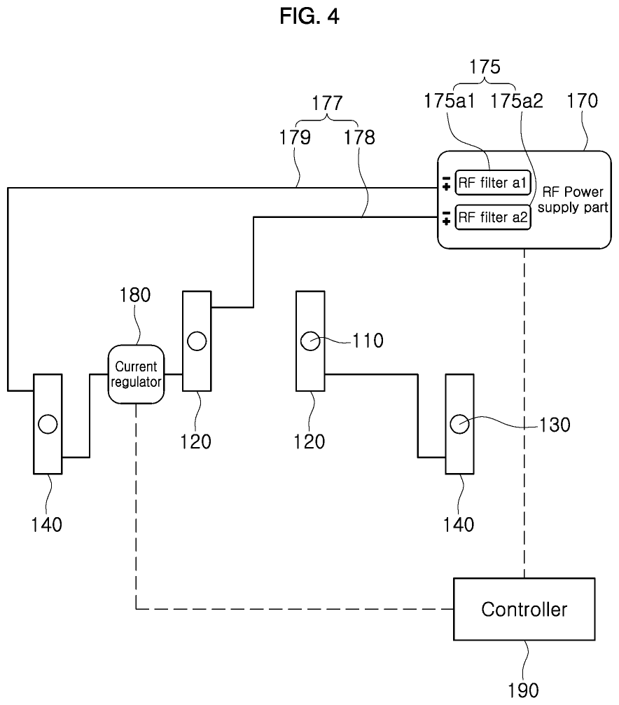

FIG. 2 is a view illustrating an embodiment of a plasma generation unit of the substrate treatment apparatus according to the present disclosure, FIG. 3 is a view illustrating a configuration of an embodiment of the plasma generation unit of the substrate treatment apparatus according to the present disclosure when viewed from above, and FIG. 4 is a view illustrating the configuration of an embodiment of the plasma generation unit of the substrate treatment apparatus according to the present disclosure taken along a side surface of the plasma generation unit.

The plasma generation unit 100 may include an inner coil 110, an inner body 120, an outer coil 130, an outer body 140, an RF power supply part 170, a current regulator 180, a controller 190, and so on.

The inner body 120 may be disposed above the window member 70. The inner coil 110 may be wound on the inner body 120. The inner coil 110 may be wound in a first direction on the inner body 120.

The outer body 140 may be disposed above the window member 70, and may be disposed on an outer side of the inner body 120. The outer coil 130 may be wound on the outer body 140. The outer coil 130 is disposed relatively outside the inner coil 110, and may be wound in a second direction that is opposite to the first direction.

That is, the outer coil 130 is disposed on the outer side of the inner coil 110, and the inner coil 110 and the outer coil 130 may be wound in opposite directions to each other. For example, when the inner coil 110 is wound in a clockwise direction, the outer coil 130 may be wound in a counterclockwise direction.

The inner body 120 and the outer body 140 may be connected to each other via a supporting leg 150, and a separation distance between the inner body 120 and the outer body 140 may be stably maintained by the supporting leg 150.

Furthermore, in the embodiment, although a structure in which the inner coil 110 is wound on an outer side surface of the inner body 120 and an outer coil 130 is wound on an inner side surface of the outer body 140 so that the inner coil 110 and the outer coil 130 face each other is illustrated in the drawings, the structure is an example. Accordingly, a structure in which the inner coil 110 is wound on an inner side surface of the inner body 120 and the outer coil 130 is wound on an outer side surface of the outer body 140 so that a space between the inner coil 110 and the outer coil 130 is blocked by the inner body 120 and the outer body 140 may be applied.

The current regulator 180 may be connected between the inner coil 110 and the outer coil 130. The current regulator 180 may connect the inner coil 110 and the outer coil 130 in series, and may convert current intensities flowing through the inner coil 110 and the outer coil 130 to be different from each other.

As an example, the current regulator 180 may increase or decrease current intensity output from the inner coil 110 and may apply the current intensity to the outer coil 130. Otherwise, the current regulator 180 may increase or decrease current intensity output from the outer coil 130 and may apply the current intensity to the inner coil 110.

The RF power supply part 170 may selectively supply power to the inner coil 110 or the outer coil 130 in order to form plasma in the treatment space of the chamber 20.

The RF power supply part 170 may supply power to the inner coil 110 and the outer coil 130 through a power supply line 177 including power supply lines 178 and 179.

The inner coil 110 may have a first side distal end 111 connected to the RF power supply part 170 via the power supply line 178, and may have a second side distal end 115 connected to the current regulator 180.

The outer coil 130 may have a first side distal end 131 connected to the current regulator 180, and may have a second side distal end 135 connected to the RF power supply part 170 via the power supply line 179.

That is, the inner coil 110 and the outer coil 130 are connected in series with each other through the current regulator 180, and a start point and an end point of a serial connection of the inner coil 110 and the outer coil 130 may be connected to the RF power supply part 170 through the power supply line 177.

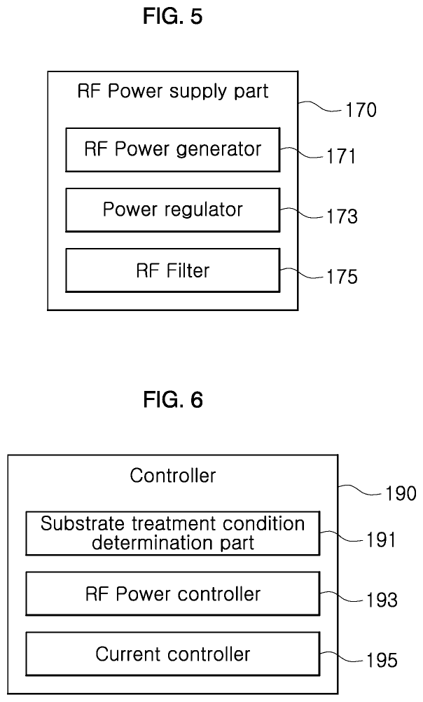

In relation to the RF power supply part 170, the RF power supply part 170 will be described with reference to FIG. 5 that is the view illustrating a configuration of an embodiment of an RF power supply part in the plasma generation unit of the substrate treatment apparatus according to the present disclosure.

The RF power supply part 170 may include an RF power generator 171, a power regulator 173, an RF filter 175, and so on.

The RF power generator 171 may supply a power to be applied to the inner coil 110 or the outer coil 130. As an example, the RF power generator 171 may supply a DC power of several mA to several A by receiving a power from outside. Of course, intensity of the DC power supplied from the RF power generator 171 may be changed as required.

The power regulator 173 may selectively supply power to the inner coil 110 and the outer coil 130. The power regulator 173 may adjust a direction and intensity of a DC power and may supply the DC power to any one of the inner coil 110 and the outer coil 130 according to a required process condition.

Preferably, the power regulator 173 may adjust and supply the DC power in response to each of the inner coil 110 and the outer coil 130. As an example, the power regulator 173 may include a power regulator A1 configured to adjust and supply a DC power to the inner coil 110, and may include a power regulator A2 configured to adjust and supply a DC power to the outer coil 130.

The RF filter 175 may filter a frequency band of a DC power output from the power regulator 173 and may apply the frequency band of the DC power to the inner coil 110 or the outer coil 130. As an example, the RF filter 175 may include various filters such as a high pass filter, a low pass filter, a band pass filter, and so on according to a required frequency band.

By placing the RF filter 175, RF radiation noise may be prevented from being introduced into the RF power supply part 170 in an RF radiation environment.

As an example, the RF filter 175 may include an RF filter A1 175al configured to filter a frequency band of a DC power applied to the outer coil 130, and may include an RF filter A2 175a2 configured to filter a frequency band of a DC power applied to the inner coil 110.

As such, the RF power supply part 170 may be configured as a single power supply that selectively supplies power to any one of the inner coil 110 and the outer coil 130. However, preferably, the RF power supply part 170 may be configured as a multi-power supply which distinguishes the inner coil 110 and the outer coil 130 and which selectively supplies individual power to each of the inner coil 110 and the outer coil 130.

The controller 190 may determine an adjustment of plasma density in the treatment space according to a substrate treatment condition, and may control the RF power supply part 170, thereby being capable of adjusting the direction and the intensity of power by selecting any one of the inner coil 110 and the outer coil 130. Furthermore, the controller 190 may control the current regulator 180 so as to selectively increase or decrease the intensity of current output from the inner coil 110 or the outer coil 130, and then may apply the intensity of current to the outer coil 130 or the inner coil 110.

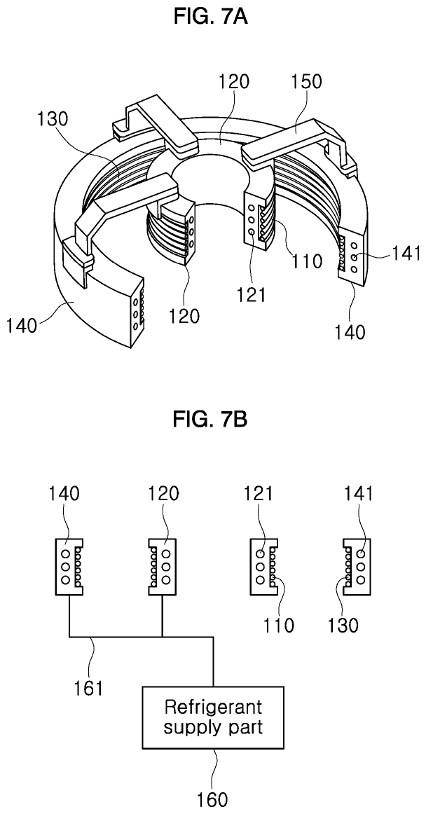

In relation to the controller 190, the controller 190 will be described with reference to FIG. 6 that is the view illustrating a configuration of an embodiment of a controller in the plasma generation unit of the substrate treatment apparatus according to the present disclosure.

The controller 190 may include a substrate treatment condition determination part 191, an RF power controller 193, a current controller 195, and so on.

The substrate treatment condition determination part 191 may determine how to adjust plasma density for each region of the treatment space according to a substrate treatment condition. For example, the substrate treatment condition determination part 191 may determine whether plasma density of a center region of a substrate is formed such that the plasma density of the center region of the substrate has a plasma density value relatively higher than or lower than a plasma density value of an outer region of the substrate according to a substrate treatment condition.

The RF power controller 193 may control the RF power supply part 170 so that the direction and the intensity of the supplied power is adjusted according to a determination result of the substrate treatment condition determination part 191 and the power is selectively supplied to the inner coil 110 and the outer coil 130.

The current controller 195 may control the current regulator 180 so that the current intensity output between the inner coil 110 and the outer coil 130 is selectively increased or decreased and the applied according to the determination result of the substrate treatment condition determination part 191.

Furthermore, each of the inner coil 110 and the outer coil 130 of the plasma generation unit 100 functions as a resistance and a heating phenomenon occurs when the inner coil 110 and the outer coil 130 are operated. Therefore, in the present disclosure, a cooling means for cooling the plasma generation unit 100 may be provided.

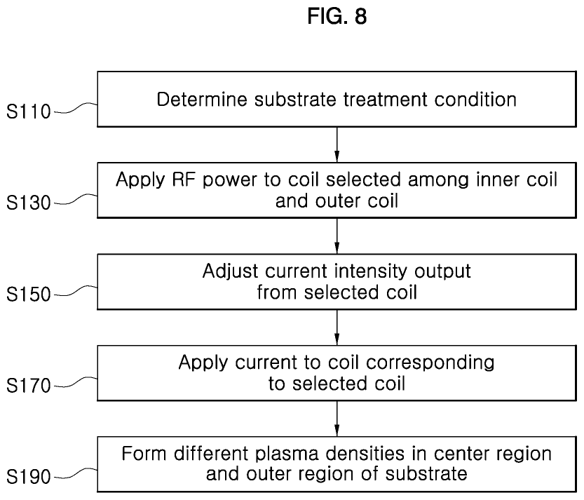

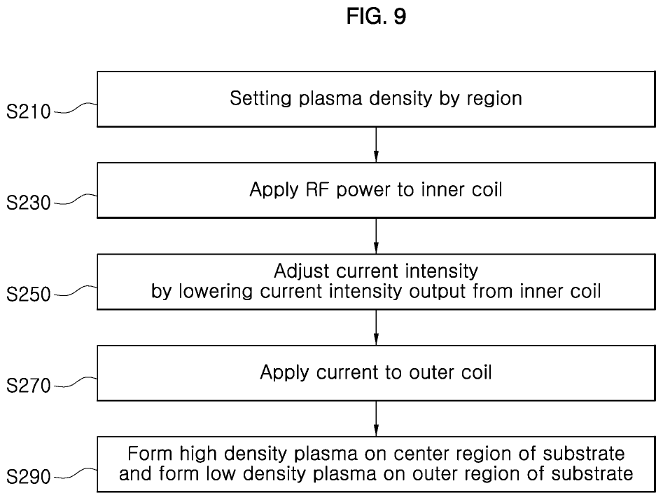

In relation to the cooling means, the cooling means will be described with reference to FIGS. 7A and 7B that are the views illustrating an embodiment of a cooling means of the plasma generation unit of the substrate treatment apparatus according to the present disclosure.

In describing the embodiment, descriptions of parts that overlap with the previously described embodiment will be omitted.

A refrigerant flow path 121 through which a refrigerant flows may be provided in an inner portion of the inner body 120 where the inner coil 110 is wound thereon. As an example, the refrigerant flow path 121 may be provided by considering an area of the inner coil 110 wound on the inner body 120. The refrigerant flow path 121 may be provided in a multi-layer structure formed along an inner circumference of the inner body 120.

A refrigerant flow path 141 through which a refrigerant flows may be provided in an inner portion of the outer body 140 where the outer coil 130 is wound thereon. As an example, the refrigerant flow path 141 may be provided by considering an area of the outer coil 130 wound on the outer body 140. The refrigerant flow path 141 may be provided in a multi-layer structure formed along an inner circumference of the outer body 140.

A refrigerant supply part 160 may supply the refrigerant to the refrigerant flow path 121 provided in the inner body 120 and to the refrigerant flow path 141 provided in the outer body 140. The refrigerant supplied from the refrigerant supply part 160 may be supplied to the refrigerant flow path 121 provided in the inner body 120 and to the refrigerant flow path 141 provided in the outer body 140 through a refrigerant line 161.

As a refrigerant supplied from the refrigerant supply part 160, various types of refrigerants such as a cooling water, a cooling gas, and so on may be applied.

According to the present disclosure, a substrate treatment apparatus capable of controlling non-uniformity of plasma density in a substrate treatment process using plasma so that a plasma sheath is capable of being adjusted and thereby being capable of precisely controlling the substrate treatment process may be provided.

In addition, in the present disclosure, a method of controlling plasma density in a substrate treatment process through the substrate treatment apparatus as described above is proposed. Hereinafter, a plasma density control method according to the present disclosure will be described through an embodiment.

Since the plasma density control method according to the present disclosure is realized in the substrate treatment apparatus according to the present disclosure, an embodiment of the substrate treatment apparatus according to the present disclosure described above will be referred to together.

The substrate treatment condition determination part 191 of the controller 190 may determine a plasma density condition for each region in the treatment space of the chamber 20 according to a corresponding substrate treatment process S110. For example, according to the corresponding substrate treatment process, whether plasma density of a substrate to be treated is formed such that a plasma density value of a center region of the substrate to be treated has a high plasma density value and a plasma density value of an outer region of the substrate to be treated has a low plasma density value may be determined. Otherwise, according to the corresponding substrate treatment process, whether plasma density of a substrate to be treated is formed such that a plasma density value of a center region of the substrate to be treated has a low plasma density value and a plasma density value of an outer region of the substrate to be treated has a high plasma density value may be determined.

A plasma density condition for each region determined by the substrate treatment condition determination part 191 of the controller 190 may be provided to the RF power controller 193 and the current controller 195.

The RF power controller 193 of the controller 190 may select a coil to which RF power is applied among the inner coil 110 and the outer coil 130 according to the plasma density condition for each region. In addition, the RF power controller 193 may determine a direction and intensity of the RF power to be applied to the selected coil according to the plasma density condition for each region.

the RF power generator 171 of the RF power supply part 170 generates the RF power to be supplied, and the power regulator 173 of the RF power supply part 170 may adjust the direction and intensity of the RF power supply according to a control of the RF power controller 193.

In addition, the RF filter 175 of the RF power supply part 170 may apply the RF power to the coil selected among the inner coil 110 and the outer coil 130 by filtering the frequency band of the RF power output from the power regulator 173.

While the RF power flows and is applied to the coil selected among the inner coil 110 and the outer coil 130, the RF power may be output to the current regulator 180.

The current controller 195 of the controller 190 may determine the degree of increase or decrease of the current intensity output from the coil to which the RF power is applied among the inner coil 110 and the outer coil 130 according to the plasma density condition for each region.

The current regulator 180 may adjust the current intensity by increasing or decreasing the current intensity output from the coil to which the RF power is applied among the inner coil 110 and the outer coil 130 according to the control of the current controller 195 S150.

In addition, the current regulator 180 may apply the current in which the intensity thereof is adjusted to the inner coil 110 and the outer coil 130 corresponding to the coil to which the RF power is applied S170.

Preferably, in a state in which the inner coil 110 is operated, the refrigerant may be supplied through the refrigerant supply part 160, and heat generated in the inner coil 110 may be cooled by the refrigerant flowing along the refrigerant flow path 121 of the inner body 120. In addition, in a state in which the outer coil 130 is operated, the refrigerant may be supplied through the refrigerant supply part 160, and heat generated in the outer coil 130 may be cooled by the refrigerant flowing along the refrigerant flow path 141 of the outer body 140.

By performing this process, the intensity and the direction of the power applied to the inner coil 110 and the outer coil 130 may be adjusted, thereby being capable of adjusting and forming the plasma density such that the plasma density of the center region of the substrate and the plasma density of the outer region of the substrate are different from each other S190.

Particularly, in the present disclosure, since the inner coil 110 and the outer coil 130 are connected in series via the current regulator 180 and the start points and the end points of the inner coil 110 and the outer coil 130 are connected to the RF power supply part 170, the power applied to the inner coil 110 and the power applied to the outer coil 130 are capable of being adjusted at the same time by using this structure, thereby being capable of more accurately and precisely controlling the plasma density.

That is, when power is individually applied to an inner coil and an outer coil and a direction and an intensity of the power are individually adjusted, there is a problem that a process parameter cannot be accurately and precisely adjusted due to increased control factors.

However, in the present disclosure, by correspondingly adjusting the direction and the intensity of the power applied to the inner coil and the outer coil, factors required to be controlled are reduced, thereby being capable of more accurately and precisely adjusting the process parameter.

A more specific operation process of the present disclosure will be described with reference to an embodiment.

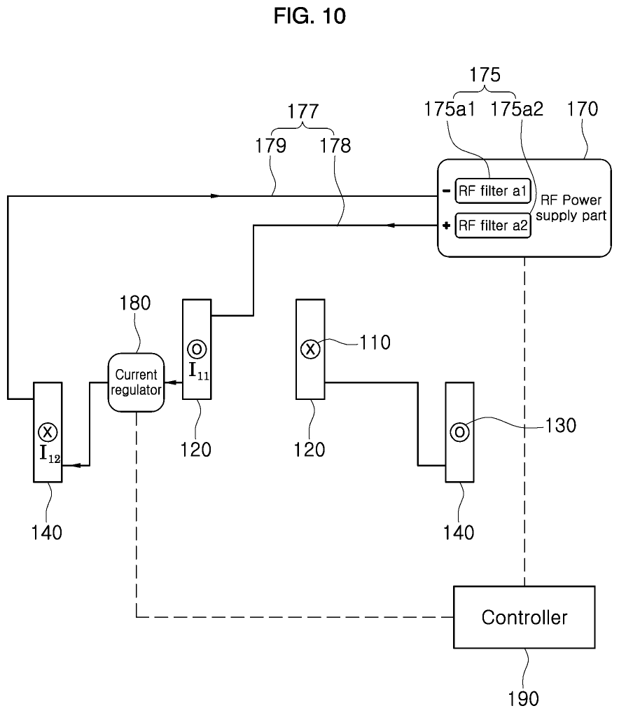

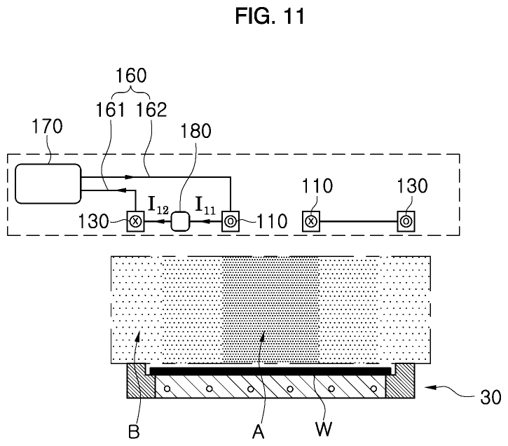

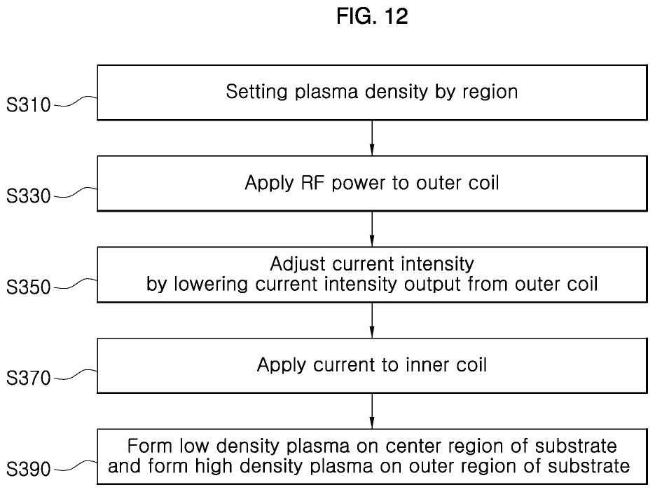

FIG. 9 is a flowchart illustrating an example of a process of controlling plasma density through the present disclosure, FIG. 10 is a view illustrating an example of an operation process of the substrate treatment apparatus according to an example of the present disclosure, and FIG. 11 is a view illustrating an example in which the plasma density is controlled through the present disclosure.

In the present embodiment, the substrate treatment condition determination part 191 of the controller 190 determines the plasma density condition for each region in the treatment space of the chamber 20 according to the corresponding substrate treatment process, and forms plasma density such that the center region of the substrate has a high plasma density value and the outer region of the substrate has a low plasma density value.

The RF power supply part 170 may adjust the direction and the intensity of the RF power according to the control of the controller 190 and then may apply the RF power to the inner coil 110 S230.

As the power is applied to the inner coil 110, a current in a counterclockwise direction may flow to the inner coil 110, and a current I11 may be output to the current regulator 180.

The current regulator 180 may switch and adjust the current I11 output from the inner coil 110 into a current I12 according to the control of the controller 190 by decreasing intensity of the current I11 S250.

The current I12 in which the current intensity thereof is decreased and adjusted by the current regulator 180 may be applied to the outer coil 130 S270. The current applied to the outer coil 130 may flow in a clockwise direction that is different from the current direction of the inner coil 110.

The current passing through the outer coil 130 may be output to the RF power supply part 170.

In this manner, as the power in which the direction and the intensity thereof are adjusted is supplied to the inner coil 110 and the intensity of the current output from the inner coil 110 is decreased and applied to the outer coil 130, the plasma density of a center region A of the substrate W may have a relatively high plasma density value, and the plasma density of an outer region B of the substrate W may have a relatively low plasma density value S290.

As illustrated in FIG. 11, in another example of forming plasma density such that the plasma density of the center region of the substrate has a relatively high plasma density value and the plasma density of the outer region of the substrate has a relatively low plasma density value, the RF power supply part 170 may adjust a direction and an intensity of a power according to the control of the controller 190 and then may apply the power to the outer coil 130.

In addition, the current regulator 180 may increase the intensity of the current output from the outer coil 130 and then may apply the current to the inner coil 110 according to the control of the controller 190.

That is, by using the current regulator 180 so as to increase the current intensity of the inner coil 110 such that the current intensity of the inner coil 110 is higher than the current intensity of the outer coil 130, the plasma density of the center region of the substrate may be formed such that the plasma density value of the center region of the substrate is higher than the plasma density value of the outer region of the substrate.

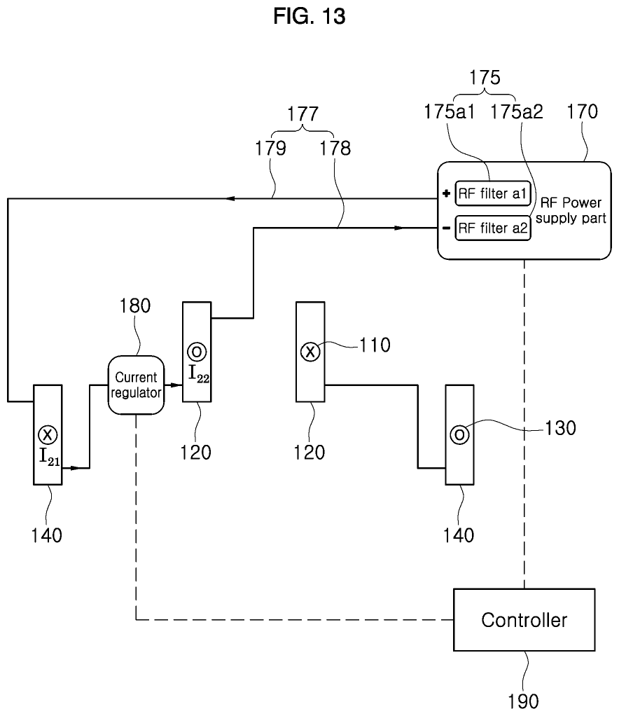

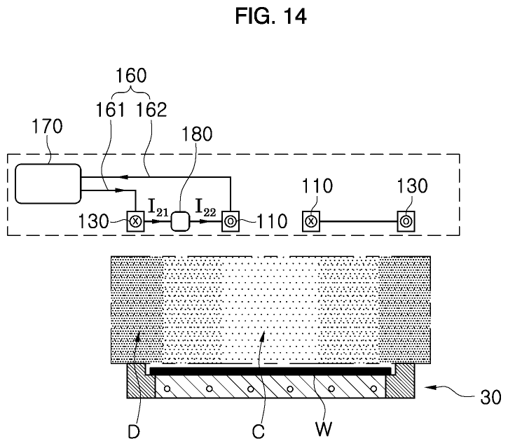

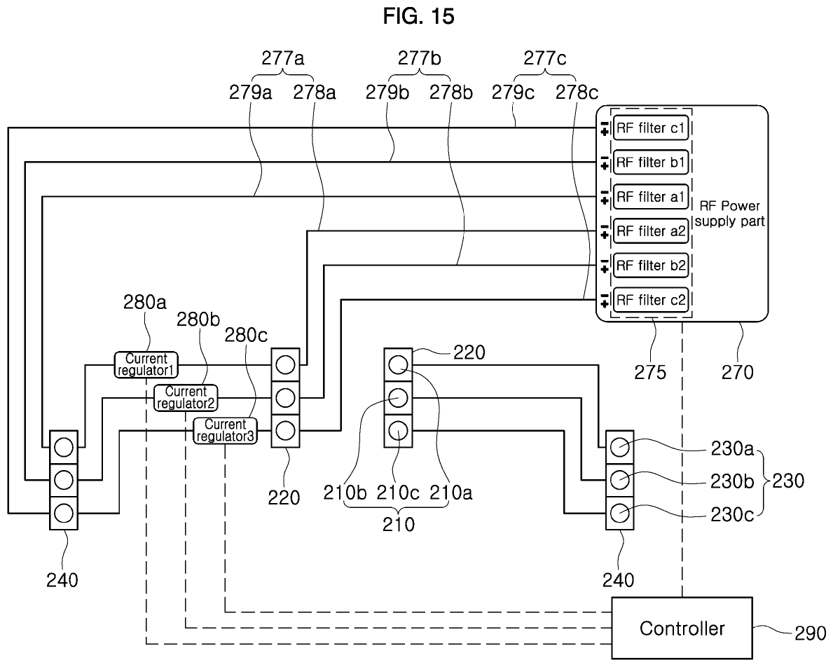

FIG. 12 is a flowchart illustrating another example of the process of controlling plasma density through the present disclosure, FIG. 13 is a view illustrating an example of the operation process of the substrate treatment apparatus according to another example of the present disclosure, and FIG. 14 is a view illustrating another example in which the plasma density is controlled through the present disclosure.

In the present embodiment, the substrate treatment condition determination part 191 of the controller 190 determines the plasma density condition for each region in the treatment space of the chamber 20 according to the corresponding substrate treatment process, and forms plasma density such that the outer region of the substrate has a high plasma density value and the center region of the substrate has a low plasma density value S310.

The RF power supply part 170 may adjust the direction and the intensity of the RF power according to the control of the controller 190 and then may apply the RF power to the outer coil 130 S310.

As the power is applied to the outer coil 130, a current in a clockwise direction may flow to the outer coil 130, and a current I21 may be output to the current regulator 180.

The current regulator 180 may switch and adjust the current I21 output from the outer coil 130 into a current I22 according to the control of the controller 190 by decreasing intensity of the current I11 S350.

The current I22 in which the current intensity thereof is decreased and adjusted by the current regulator 180 may be applied to the inner coil 110 S370. The current applied to the inner coil 110 may flow in a counterclockwise direction that is different from the current direction of the outer coil 130.

The current passing through the inner coil 110 may be output to the RF power supply part 170.

In this manner, as the power in which the direction and the intensity thereof are adjusted is supplied to the outer coil 130 and the intensity of the current output from the outer coil 130 is decreased and applied to the inner coil 110, the plasma density of an outer region D of the substrate W may have a relatively high plasma density value, and the plasma density of a center region C of the substrate W may have a relatively low plasma density value S390.

As illustrated in FIG. 14, in another example of forming plasma density such that the plasma density of the outer region of the substrate has a relatively high plasma density value and the plasma density of the center region of the substrate has a relatively low plasma density value, the RF power supply part 170 may adjust a direction and an intensity of a power according to the control of the controller 190 and then may apply the power to the inner coil 110.

In addition, the current regulator 180 may increase the intensity of the current output from the inner coil 110 and then may apply the current to the outer coil 130 according to the control of the controller 190.

That is, by using the current regulator 180 so as to increase the current intensity of the outer coil 130 such that the current intensity of the outer coil 130 is higher than the current intensity of the inner coil 110, the plasma density of the outer region of the substrate may be formed such that the plasma density value of the outer region of the substrate is higher than the plasma density value of the center region of the substrate.

The plasma generation unit of the substrate treatment apparatus according to the present disclosure may be modified in various ways. For an example, the inner coil and the outer coil may be configured in a multi-layer structure.

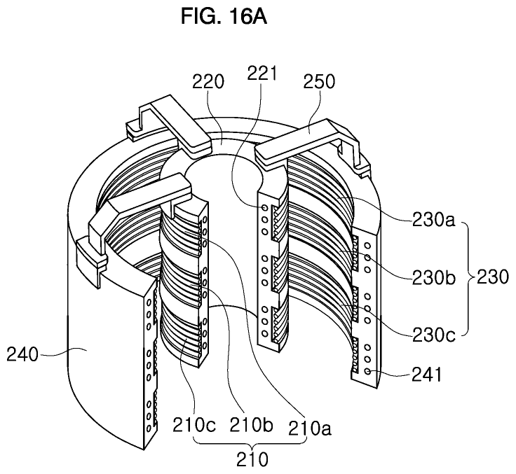

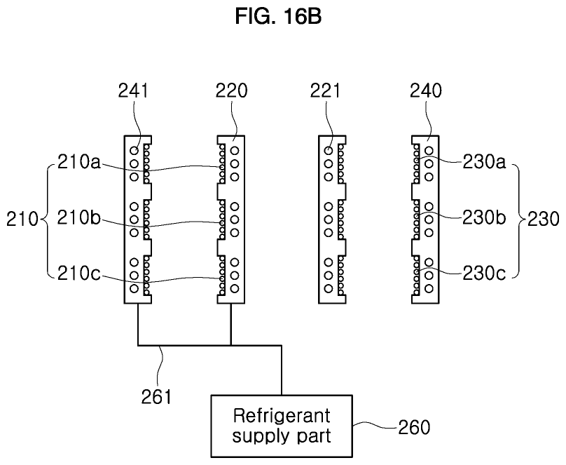

FIG. 15 is a view illustrating another embodiment of the plasma generation unit of the substrate treatment apparatus according to the present disclosure, and FIGS. 16A and 16B are views illustrating another embodiment of the cooling means of the plasma generation unit of the substrate treatment apparatus according to the present disclosure.

In describing the embodiment, descriptions of parts that overlap with the previously described embodiment will be briefly described or will be omitted.

The plasma generation unit of the substrate treatment apparatus according to the present disclosure may include a plurality of inner coils 210 having a multi-layer structure, and may include a plurality of outer coils 230 having a multi-layer structure.

A first inner coil 210a, a second inner coil 210b, and a third inner coil 210c may be wound in a first direction on the inner body 220. Each inner coil 210a, 210b, and 210c may be wound sequentially by being spaced apart from each other along a height direction of the inner body 220. Each inner coil 210a, 210b, and 210c may be electrically separated from each other. For this purpose, the inner body 220 may be provided with a partition wall partitioning and separating the inner coils 210a, 210b, and 210c from each other.

A first outer coil 230a, a second outer coil 230b, and a third outer coil 230c may be wound in a second direction on the outer body 240. Each outer coil 230a, 230b, and 230c may be wound sequentially by being spaced apart from each other along a height direction of the outer body 240. Each outer coil 230a, 230b, and 230c may be electrically separated from each other. For this purpose, the outer body 240 may be provided with a partition wall partitioning and separating the outer coils 230a, 230b, and 230c from each other.

The first inner coil 210a and the first outer coil 230a may be connected in series with each other via a first current regulator 280a, the second inner coil 210b and the second outer coil 230b may be connected in series with each other via a second current regulator 280b, and the third inner coil 210c and the third outer coil 230c may be connected in series with each other via a third current regulator 280c.

Each of the current regulators 280a, 280b, and 280C may convert current intensities flowing to the corresponding plurality of inner coils 210 and the corresponding plurality of outer coils 230.

The RF power supply part 270 may selectively supply power to the plurality of inner coils 210 and the plurality of outer coils 230. The RF power supply part 270 may include a multi-power supply capable of selectively supplying individual power to each of the inner coils 210a, 210b, and 210c and each of the outer coils 230a, 230b, and 230c.

The RF power supply part 270 may include an RF power generator, a plurality of power regulators, a plurality of RF filters, and so on.

The RF power generator may supply a power to be applied to the inner coil 110 or the outer coil 130.

The power regulator may be provided with a plurality of power regulators corresponding to the plurality of inner coils 210a, 210b, and 210c and the plurality of outer coils 230a, 230b, and 230c. The power regulators may adjust the intensity and the direction of the power corresponding to each coil.

The RF filter 275 may be provided with a plurality of RF filters 275 corresponding to the plurality of inner coils 210a, 210b, and 210c and the plurality of outer coils 230a, 230b, and 230c. The RF filter 275 may adjust the frequency band output to each coil.

A plurality of power supply lines 277a, 277b, and 277c corresponding to each of the inner coils 210a, 210b, and 210c and each of the outer coils 230a, 230b, and 230c and being configured to supply the power of the RF power supply part 270 may be provided.

The first inner coil 210a and the first outer coil 230a may be connected in series with each other, so that a distal end of the first inner coil 210a and a distal end of the first outer coil 230a may be connected to the RF power supply part 270 via first power supply lines 278a and 279a.

Similarly, the second inner coil 210b and the second outer coil 230b may be connected in series with each other and may be connected to the RF power supply part 270 via second power supply lines 278b and 279b, and the third inner coil 210c and the third outer coil 230c may be connected in series with each other and may be connected to the RF power supply part 270 via third power supply lines 278c and 279c.

The controller 290 may control the RF power supply part 270 such that the power is selectively applied to the plurality of inner coils 210 and the plurality of outer coils 230. In addition, the controller 290 may control the plurality of current regulators 280a, 280b, and 280c so that the current intensities between the plurality of inner coils 210 and the plurality of outer coils 230 are individually decreased or increased.

Furthermore, a refrigerant flow path 221 in which the refrigerant flows may be provided inside the inner body 220 where the inner coil 210 is wound thereon, and a refrigerant flow path 241 in which the refrigerant flows may be provided inside the outer body 240 where the outer coil 230 is wound thereon.

The refrigerant flow path 221 of the inner body 220 may be provided by corresponding to a portion on which the plurality of inner coils 210 is wound, and the refrigerant flow path 241 of the outer body 240 may be provided by corresponding to a portion on which the plurality of outer coils 230 is wound.

A refrigerant supply part 260 may supply the refrigerant to the refrigerant flow path 221 provided in the inner body 220 and to the refrigerant flow path 241 provided in the outer body 240 through a refrigerant line 261.

As such, the plasma generation unit of the substrate treatment apparatus according to the present disclosure may be formed of a multi-layer structure in which the plurality of inner coils and the plurality of outer coils are stacked.

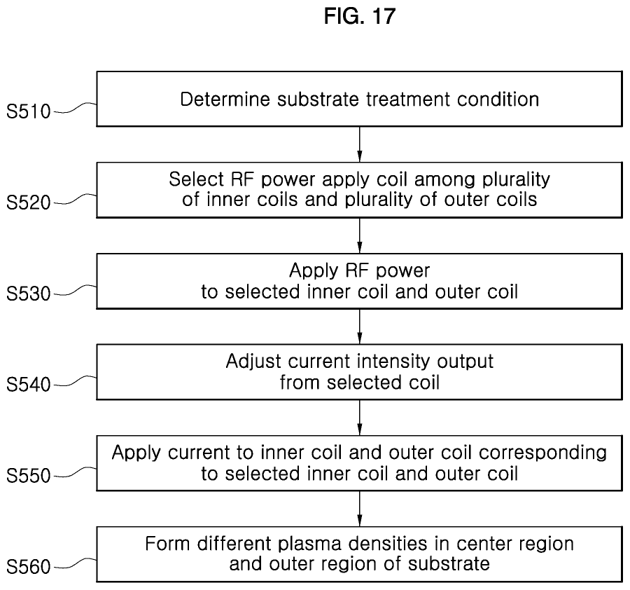

FIG. 17 is a flowchart illustrating another embodiment of the plasma density control method according to the present disclosure.

The present embodiment may be a method of controlling plasma density in the substrate treatment apparatus having the plasma generation unit having the multi-layer structure in which the plurality of inner coils and the plurality of outer coils are stacked, the substrate treatment apparatus being illustrated in FIG. 15 and FIGS. 16A and 16B.

The controller 290 may determine a plasma density condition for each region in the treatment space of the chamber 20 according to a corresponding substrate treatment process S510.

The controller 290 may select and combine the coil to which RF power is applied among the plurality of inner coils 210 and the plurality of outer coils 230 according to the plasma density condition for each region S520.

For example, a combination in which the RF power is applied to the plurality of inner coils 210 by selecting all of the plurality of inner coils 210 and the RF power is not applied to the plurality of outer coils 230 may be configured.

Alternatively, a combination in which at least one of the plurality of inner coils 210 is selected and at least one of the plurality of outer coils 230 corresponding to the inner coil 210 that is not selected from the plurality of inner coils 210 may be configured.

That is, in order to precisely adjust the plasma density for each region according to the plasma density condition for each region, a coil to which RF power is applied may be selected and combined from the plurality of inner coils 210 and the plurality of outer coils 230.

The RF power supply part 270 may adjust the direction and the intensity of each RF power to be applied to the selected inner coil and the selected outer coil, and then may apply the RF power to the selected inner coil and the selected outer coil S530.

As the RF power is applied and flows to the selected inner coil and the selected outer coil, the RF power may be output to each of the plurality of current regulators 280a, 280b, and 280c.

Each of the current regulators 280a, 280b, and 280c may adjust the current intensity by increasing or decreasing the current intensity output from the inner coil and the outer coil to which the RF power is applied according to the control of the controller 290 S540.

In addition, each of the current regulators 280a, 280b, and 280c may apply the current in which the intensity thereof is adjusted to the inner coil 210 and the outer coil 230 corresponding to the coil to which the RF power is applied S550.

By performing this process, the intensity and the direction of the power applied to the plurality of inner coils 210 and the plurality of outer coils 230 may be more precisely adjusted, thereby being capable of more precisely adjusting and forming the plasma density of the center region and the outer region of the substrate S560.

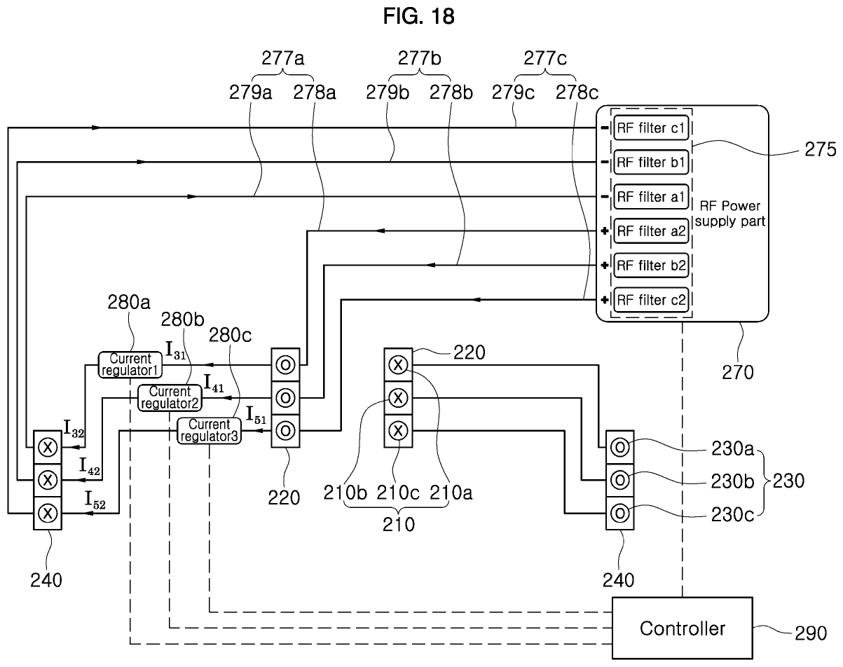

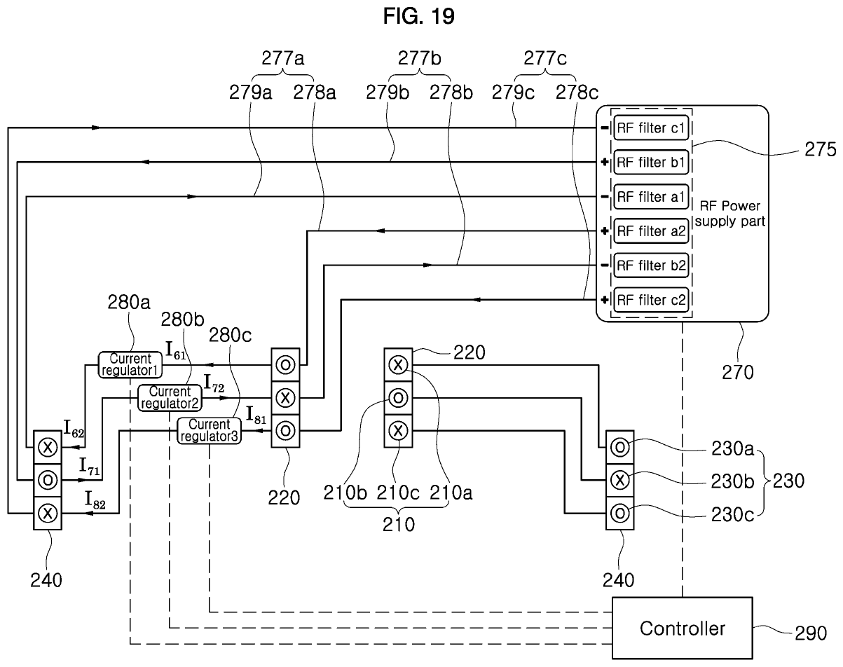

An operation process of the plasma generation unit in the substrate treatment apparatus of the present disclosure will be described with reference to FIG. 18 and FIG. 19.

As an example illustrated in FIG. 18, a combination in which the controller 290 selects all of the plurality of inner coils 210a, 210b, and 210c and applies RF power according to the plasma density condition for each region may be configured.

According to the control of the controller 290, the RF power supply part 270 may adjust the direction and the intensity of the RF power to be applied to each of the inner coils 210a, 210b, and 210c, and then may apply the RF power to each of the inner coils 210a, 210b, and 210c through each of the power supply lines 278a, 278b, and 278c.

Each of currents I31 I41, and I51 may be applied to the each of the current regulators 280a, 280b, and 280c from the each of the inner coils 210a, 210b, and 210c. Each of the current regulators 280a, 280b, and 280c may decrease each current intensity according to the control of the controller 290, and then may apply each of regulated currents I32, I42, and I52 to each of the outer coils 230a, 230b, and 230c.

Currents output from each of the outer coils 230a, 230b, and 230c may be introduced into the RF power supply part 270 through each of the power supply lines 279a, 279b, and 279c.

Furthermore, in contrast to the example illustrated in FIG. 18, a combination in which all of the plurality of outer coils 230a, 230b, and 230c are selected and the RF power is applied to the all of the plurality of outer coils 230a, 230b, and 230c may be configured, and the intensity of the current may be decreased from each of the outer coils 230a, 230b, and 230c and then the current may be applied to each of the inner coils 210a, 210b, and 210c.

In addition, a configuration of applying the RF power and adjusting the current may be variously combined. As an example illustrated in FIG. 19, a combination in which the controller 290 selects the first inner coil 210a, the third inner coil 210c, and the second outer coil 230b and then apply the RF power to the selected coils according to the plasma density condition for each region may be configured.

The RF power supply part 270 may adjust the direction and the intensity of the RF power and then may apply the RF power to a combination of the first inner coil 210a, the third inner coil 210c, and the second outer coil 230b that are selected according to the control of the controller 290.

Currents I61 and I81 may be respectively applied to the first current regulator 280a and the third current regulator 280c from the first inner coil 210a and the third inner coil 210c. In addition, a current I71 may be applied to the second current regulator 280b from the second outer coil 230b.

The first current regulator 280a and the third current regulator 280c may adjust the current intensity by decreasing the current intensity according to the control of the controller 290, and then may apply adjusted currents I62 and I82 to the first outer coil 230a and the third outer coil 230c, respectively. In addition, the second current regulator 280b may adjust the current intensity by decreasing the current intensity according to the control of the controller 290, and then may apply an adjusted current I72 to the second inner coil 210b.

As described above, in the present disclosure, plasma density for each region may be more precisely adjusted by configuring the plurality of inner coils and the plurality of outer coils to be corresponded to each other and to be connected in series with each other and by adjusting and combining the intensity and the direction of the power.

Although the embodiments of the present disclosure have been disclosed for illustrative purposes, those skilled in the art will appreciate that various modifications, additions, and substitutions are possible, without departing from the scope and spirit of the present disclosure. Accordingly, embodiments disclosed in the present disclosure are provided for describing the present disclosure and are not intended to limit the technical ideas of the present disclosure. The technical ideas of the present disclosure are not limited to the embodiments. The scope of the present disclosure should be construed as being covered by the scope of the appended claims, and all technical ideas falling within the scope of the claims should be construed as being included in the scope of the present disclosure.

What is claimed is:

1. A substrate treatment apparatus comprising:
a chamber provided with a treatment space in which a plasma substrate treatment process is performed;
a substrate supporting unit which is disposed in the treatment space and on which a substrate to be treated is seated;
an inner coil wound in a first direction;
an outer coil disposed outside the inner coil and wound in a second direction opposite to the first direction;
a current regulator connecting the inner coil and the outer coil in series between the inner coil and the outer coil, the current regulator being configured to convert a current; and
an RF power supply part configured to selectively supply power to the inner coil or the outer coil so as to form plasma in the treatment space.

2. The substrate treatment apparatus of claim 1, wherein a first side distal end of the inner coil and a first side distal end of the outer coil are connected to the RF power supply part, and a second side distal end of the inner coil and a second side distal end of the outer coil are connected to the current regulator, so that the inner coil and the outer coil are connected with each other in series via the current regulator.

3. The substrate treatment apparatus of claim 1, further comprising a controller configured to control the RF power supply part so that power intensity is adjusted and RF power is selectively supplied to the inner coil and the outer coil, the controller being configured to control the current regulator so that current intensity between the inner coil and the outer coil is changed.

4. The substrate treatment apparatus of claim 3, wherein the controller is configured to adjust plasma density by controlling the power of the RF power supply part and by controlling the current of the current regulator such that a plasma density value of a center region of the substrate which is to be treated and which is seated on the substrate supporting unit and a plasma density value of an outer region of the substrate are different from each other.

5. The substrate treatment apparatus of claim 1, wherein the RF power supply part is configured to apply the power to the inner coil, and the current regulator is configured to increase or decrease intensity of current output from the inner coil and to apply the current to the outer coil.

6. The substrate treatment apparatus of claim 1, wherein the RF power supply part is configured to apply the power to the outer coil, and the current regulator is configured to decrease or increase intensity of current output from the outer coil and to apply the current to the inner coil.

7. The substrate treatment apparatus of claim 1, wherein the RF power supply part comprises:
an RF power generator configured to generate RF power;
a power regulator configured to adjust a supply direction and intensity of the power; and
an RF filter configured to adjust a frequency band of the RF power and to output the RF power.

8. The substrate treatment apparatus of claim 1, wherein the inner coil comprises a plurality of inner coils disposed in a multi-layer structure and electrically separated from each other, the outer coil comprises a plurality of outer coils disposed in a multi-layer structure and electrically separated from each other corresponding to the plurality of inner coils, and the current regulator comprises a plurality of current regulators which is respectively connected between the plurality of inner coils and the plurality of outer coils corresponding to the plurality of inner coils and which is configured to convert the current.

9. The substrate treatment apparatus of claim 8, wherein the RF power supply part is configured to selectively apply the power to the plurality of inner coils and the plurality of outer coils, and the current regulator is configured to individually decrease or increase intensity of the current between the plurality of inner coils and the plurality of outer coils.

10. The substrate treatment apparatus of claim 8, wherein the RF power supply part comprises:
an RF power generator configured to generate RF power;
a plurality of power regulators configured to individually adjust a supply direction and intensity of the power by corresponding to the plurality of inner coils and the plurality of outer coils; and
a plurality of RF filters configured to adjust a frequency band of each RF power by corresponding to the plurality of inner coils and the plurality of outer coils and to output the RF power.

11. The substrate treatment apparatus of claim 1, further comprising:
an inner body on which the inner coil is wound and in which a refrigerant flow path is formed therein;
an outer body on which the outer coil is wound and in which a refrigerant flow path is formed therein; and
a refrigerant supply part configured to supply a refrigerant to the refrigerant flow path of the inner body and the refrigerant flow path of the outer body.

12. A plasma density control method comprising:
a power applying process in which RF power is applied through an RF power supply part to a selected coil among an inner coil and an outer coil that correspond to each other;
a current conversion process in which intensity of a current output from the selected coil is increased or decreased and the current is applied to a coil corresponding to the selected coil through a current regulator; and
a plasma forming process in which plasma density is formed such that a plasma density value of a center region of a substrate to be treated and a plasma density value of an outer region of the substrate to be treated are different from each other.

13. The plasma density control method of claim 12, wherein the power applying process is performed such that the RF power is applied to the inner coil through the RF power supply part, the current conversion process is performed such that intensity of a current output from the inner coil is decreased and applied to the outer coil through the current regulator, and the plasma forming process is performed to form the plasma density such that the plasma density value of the center region of the substrate to be treated is higher than the plasma density value of the outer region of the substrate to be treated.

14. The plasma density control method of claim 12, wherein the power applying process is performed such that the RF power is applied to the outer coil through the RF power supply part, the current conversion process is performed such that intensity of a current output from the outer coil is decreased and applied to the inner coil through the current regulator, and the plasma forming process is performed to form the plasma density such that the plasma density value of the outer region of the substrate to be treated is higher than the plasma density value of the center region of the substrate to be treated.

15. The plasma density control method of claim 12, wherein the power applying process is performed such that the RF power is applied to the inner coil through the RF power supply part, the current conversion process is performed such that intensity of a current output from the inner coil is increased and applied to the outer coil through the current regulator, and the plasma forming process is performed to form the plasma density such that the plasma density value of the center region of the substrate to be treated is higher than the plasma density value of the outer region of the substrate to be treated.

16. The plasma density control method of claim 12, wherein the power applying process is performed such that the RF power is applied to the outer coil through the RF power supply part, the current conversion process is performed such that intensity of a current output from the outer coil is increased and applied to the inner coil through the current regulator, and the plasma forming process is performed to form the plasma density such that the plasma density value of the outer region of the substrate to be treated is higher than the plasma density value of the center region of the substrate to be treated.

17. The plasma density control method of claim 12, wherein the power applying process is performed such that the RF power is applied through the RF power supply part to each inner coil comprising a plurality of inner coils, the current conversion process is performed such that intensity of a current output from each of the inner coils is decreased and applied through the current regulator to each outer coil comprising a plurality of outer coils, and the plasma forming process is performed to form the plasma density such that the plasma density value of the center region of the substrate to be treated is higher than the plasma density value of the outer region of the substrate to be treated.

18. The plasma density control method of claim 12, wherein the power applying process is performed such that the RF power is applied through the RF power supply part to each outer coil comprising a plurality of outer coils, the current conversion process is performed such that intensity of a current output from each of the outer coils is decreased and applied through the current regulator to each inner coil comprising a plurality of inner coils, and the plasma forming process is performed to form the plasma density such that the plasma density value of the outer region of the substrate to be treated is higher than the plasma density value of the center region of the substrate to be treated.

19. The plasma density control method of claim 12, wherein the power applying process is performed such that the RF power is applied through the RF power supply part to each of at least one inner coil selected among the inner coil comprising a plurality of inner coils and at least one outer coil corresponding to the inner coil that is not selected, the current conversion process is performed such that intensity of a current output from each of at least one outer coil to which the RF power is applied and at least one inner coil to which the RF power is applied is increased or decreased and then is applied through the current regulator to each of at least one outer coil to which the RF power is not applied and at least one inner coil to which the RF power is not applied, and the plasma forming process is performed to form the plasma density such that the plasma density value of the outer region of the substrate to be treated and the plasma density value of the center region of the substrate to be treated are different from each other.

20. A substrate treatment apparatus comprising:
a chamber provided with a treatment space in which a plasma substrate treatment process is performed;
a substrate supporting unit which is disposed in the treatment space and on which a substrate to be treated is seated;
an inner coil wound in a first direction;
an inner body on which the inner coil is wound and in which a refrigerant flow path is formed therein;
an outer coil disposed relatively outside the inner coil and wound in a second direction opposite to the first direction;
an outer body on which the outer coil is wound and in which a refrigerant flow path is formed therein;
a current regulator connecting the inner coil and the outer coil in series between the inner coil and the outer coil, the current regulator being configured to convert a current;
an RF power supply part configured to selectively supply power to the inner coil or the outer coil so as to form plasma in the treatment space;
a refrigerant supply part configured to supply a refrigerant to the refrigerant flow path of the inner body and the refrigerant flow path of the outer body; and
a controller configured to control the RF power supply part so that power intensity is adjusted and RF power is selectively supplied to the inner coil and the outer coil, the controller being configured to control the current regulator so that current intensity between the inner coil and the outer coil is changed, thereby adjusting plasma density such that a plasma density value of a center region of the substrate to be treated and a plasma density value of an outer region of the substrate to be treated are different from each other.
